(19) United States
(12) Patent Application Publication
(10) Pub. No.: US 2010/0308409 A1
(43) Pub. Date: Dec. 9, 2010

(54) FINFET STRUCTURES WITH FINS HAVING STRESS-INDUCING CAPS AND METHODS FOR FABRICATING THE SAME

(75) Inventors: Frank S. Johnson, Wappinger Falls, NY (US); Scott Luning, Poughkeepsie, NY (US); Michael J. Hargrove, Clinton Corners, NY (US)

Correspondence Address: Ingrassia Fisher & Lorenz, P.C. (GF), 7010 E. Cochise Rd., Scottsdale, AZ, 85253, US

(73) Assignee: GLOBALFOUNDRIES INC., Grand Cayman (KY)

(21) Appl. No.: 12/480,263

(22) Filed: Jun. 8, 2009

(51) Int. Cl. H01L 27/088; H01L 21/308; H01L 21/31; H01L 21/8234

(52) U.S. Cl. 257/368; 438/703; 438/587; 257/E27.06; 257/E21.231; 257/E21.24; 257/E21.616

(57) ABSTRACT

FinFET structures with fins having stress-inducing caps and methods for fabricating such FinFET structures are provided. In an exemplary embodiment, a method for forming stressed structures comprises forming a first stress-inducing material overlying a semiconductor material and forming spacers overlying the first stress-inducing material. The first stress-inducing material is etched using the spacers as an etch mask to form a plurality of first stress-inducing caps. The semiconductor material is etched using the plurality of first stress-inducing caps as an etch mask.

### FIELD OF THE INVENTION

The present invention generally relates to semiconductor devices and methods for fabricating semiconductor devices, and more particularly relates to FinFET structures with fins having stress-inducing caps and methods for fabricating the same.

### BACKGROUND OF THE INVENTION

In contrast to traditional planar metal-oxide-semiconductor field-effect transistors (MOSFETs), which are fabricated using conventional lithographic fabrication methods, nonplanar FETs incorporate various vertical transistor structures. One such semiconductor structure is the “FinFET,” which takes its name from the multiple thin silicon “fins” that are used to form the respective gate channels, and which are typically on the order of tens of nanometers in width.

More particularly, referring to the exemplary prior art nonplanar FET structure shown in FIG. 1, a FinFET 100 generally includes two or more parallel silicon fin structures (or simply “fins”) 104 and 106. These structures are typically formed on a silicon-on-insulator (SOI) substrate (not shown), with fins 104 and 106 extending between a common drain electrode and a common source electrode (not shown). A conductive gate structure 102 “wraps around” three sides of both fins 104 and 106, and is separated from the fins by a standard gate oxide layer 103. Fins 104 and 106 may be suitably doped to produce the desired FET polarity, as is known in the art, such that a gate channel is formed within the near surface of the fins adjacent to gate oxide 103. The width of the gate, indicated by double-headed arrow 108, determines the effective channel length of the device.

While the use of stress-inducing materials is a well-known technique to increase the mobility of carriers within gate channels of planar MOSFETs, the use of such materials in FinFET structures is more difficult because of the complex topography of FinFET structures. For example, memory strain layers can be deposited on planar MOSFET gates, which typically are the main component of the MOSFET topography, and can then be relatively easily removed once the strain of the strain layer is transferred to the gate channel. However, it is often difficult to remove a deposited strain layer from between the narrow spaces and/or crevices of the complex topography of a FinFET structure. Accordingly, remnants of the strain layer can remain within the narrow spaces and/or crevices and adversely affect operation of the resulting FinFET device. Removal of such strain layers is also difficult when different stress-inducing layers are deposited over n-channel FinFET (NFET) structures and p-channel FinFET (PFET) structures. In addition, the application of stress by such stress-inducing materials presents challenges because the interaction of the materials with the topography of the FinFET can cause an over-enhancement of the strain in various locations.

Accordingly, it is desirable to provide methods for fabricating strained semiconductor fins that do not require removal of strain layers from between the fins. It also is desirable to provide methods for fabricating FinFET structures with fins having stress-inducing caps. In addition, it is desirable to provide FinFET structures with fins having stress-inducing caps. Furthermore, other desirable features and characteristics of the present invention will become apparent from the subsequent detailed description of the invention and the appended claims, taken in conjunction with the accompanying drawings and this background of the invention.

### BRIEF SUMMARY OF THE INVENTION

FinFET structures with fins having stress-inducing caps and methods for fabricating such FinFET structures are provided. In an exemplary embodiment of the present invention, a method for forming stressed structures comprises forming a first stress-inducing material overlying a semiconductor material and forming spacers overlying the first stress-inducing material. The first stress-inducing material is etched using the spacers as an etch mask to form a plurality of first stress-inducing caps. The semiconductor material is etched using the plurality of first stress-inducing caps as an etch mask.

In accordance with another exemplary embodiment of the present invention, a method for fabricating stressed fins of a FinFET device comprises depositing a first stress-inducing material overlying a first portion and a second portion of a semiconductor material. The first stress-inducing material is removed from overlying the second portion of the semiconductor material and a second stress-inducing material is deposited overlying the first stress-inducing material and the second portion of the semiconductor material. The second stress-inducing material is at least substantially removed from the first stress-inducing material. Sacrificial mandrels are formed overlying the first stress-inducing material and the second stress-inducing material. The sacrificial mandrels have sidewalls. Sidewall spacers are formed about the sidewalls of the sacrificial mandrels and the sacrificial mandrels are removed, leaving the sidewall spacers substantially in tact. The first stress-inducing material is etched using the sidewall spacers as an etch mask to form a plurality of first stress-inducing caps and the second stress-inducing material is etched using the sidewall spacers as an etch mask to form a plurality of second stress-inducing caps. The semiconductor material is etched using the plurality of first stress-inducing caps and the plurality of second stress-inducing caps as an etch mask to form fins having sidewalls. A gate insulator layer is formed about the sidewalls of the fins. A gate electrode-forming material is formed overlying the gate insulator layer.

In accordance with a further exemplary embodiment, a FinFET device comprises a plurality of fin structures overlying a semiconductor substrate. Each of the plurality of fin structures has sidewalls and a surface orthogonal to the sidewalls and parallel to but remote from a surface of the semiconductor substrate. The FinFET device also comprises a plurality of stress-inducing caps. Each of the plurality of stress-inducing caps is disposed on the surface of one of the plurality of fin structures. In addition, the FinFET device comprises a gate insulator layer about the sidewalls of the plurality of fin structures and a gate electrode overlying the gate insulator layer.

### BRIEF DESCRIPTION OF THE DRAWINGS

The present invention will hereinafter be described in conjunction with the following drawing figures, wherein like numerals denote like elements, and wherein:

FIG. 1 is an isometric schematic view of a FinFET structure available in the prior art; and

FIGS. 2-8 illustrate, in cross section, methods for fabricating FinFET structures with fins having stress-inducing caps, in accordance with exemplary embodiments of the present invention.

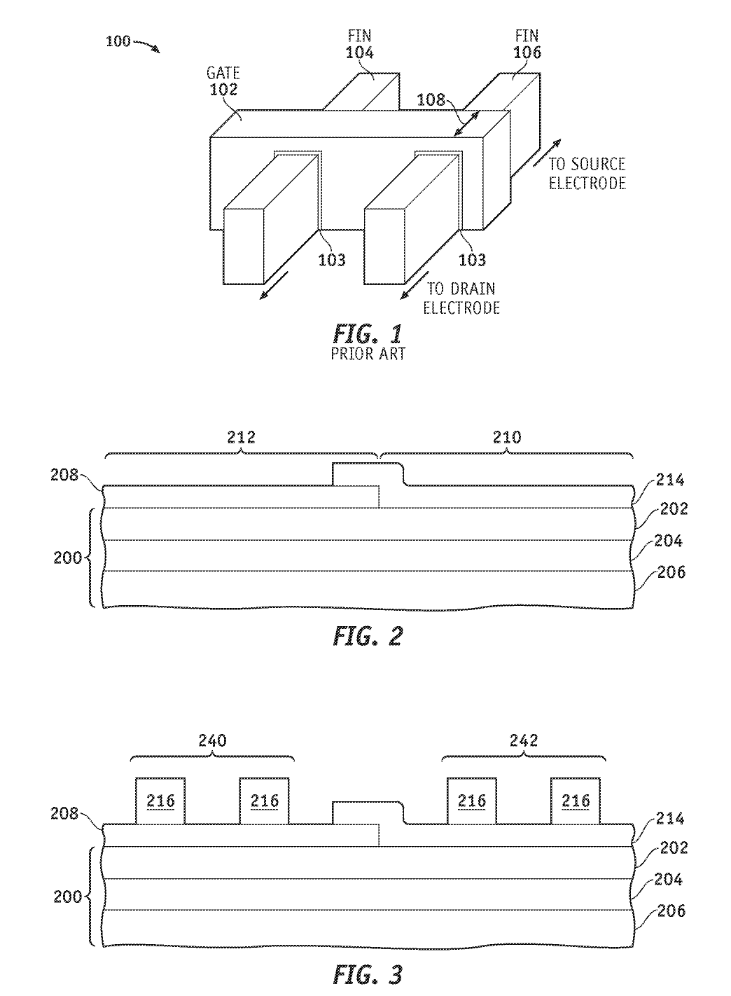

### DETAILED DESCRIPTION OF THE INVENTION

The following detailed description of the invention is merely exemplary in nature and is not intended to limit the invention or the application and uses of the invention. Furthermore, there is no intention to be bound by any theory presented in the preceding background of the invention or the following detailed description of the invention.

FIGS. 2-8 illustrate, in cross section, methods for fabricating semiconductor fins having stress-inducing caps, in accordance with exemplary embodiments of the present invention. While the various embodiments particularly refer to the fabrication of FinFET devices having fins with stress-inducing caps, it will be understood that the invention is not so limited and that the methods can be used to form various semiconductor fin structures. The stress-inducing caps are formed before the fins are formed. In this regard, the stress-inducing material from which the caps are formed can be removed easily upon formation of the caps. In addition, the stress-inducing caps are disposed at a top surface of the fins. Because the channel of a FinFET device is disposed at the vertical sidewalls of the fin adjacent to a gate structure, a stress-inducing cap disposed on the top surface of the fin perpendicular to these vertical sidewalls induces a discrete stress in the crystal lattice of the fin uniformly to both vertical sidewalls. The stress-inducing cap can apply either a compressive stress to the top surface of the fin to induce a tensile stress in channels of the fin, such as an underlying n-channel fin, or a tensile stress to the top surface to induce a compressive stress in channels of the fin, such as an underlying p-channel fin. Thus, the stress is induced directly upon the channel of the device.

Referring to FIG. 2, in accordance with exemplary embodiments of the present invention, methods for fabricating FinFET structures include the step of forming a first stress-inducing material 208 on a semiconductor substrate 200. As used herein, the term “semiconductor substrate” will be used to encompass semiconductor materials conventionally used in the semiconductor industry from which to make electrical devices. Semiconductor materials include monocrystalline silicon materials, such as the relatively pure or lightly impurity-doped monocrystalline silicon materials typically used in the semiconductor industry, as well as polycrystalline silicon materials, and silicon admixed with other elements such as germanium, carbon, and the like. In addition, “semiconductor material” encompasses other materials such as relatively pure and impurity-doped germanium, gallium arsenide, zinc oxide, glass, and the like. The semiconductor material is preferably a silicon substrate. The silicon substrate may be a bulk silicon wafer or, as illustrated, may comprise a thin semiconductor material, such as a silicon-comprising material 202, and any overlying materials, on a buried oxide layer 204 disposed on a support substrate 206. Support substrate 206 is preferably a silicon substrate, which can be either N-type or P-type silicon. Here, the silicon-comprising material 202 and the buried oxide layer 204 form what is commonly known as a silicon-on-insulator (SOI) structure that, in turn, is supported by support substrate 206.

The stress-inducing material 208 can be any material that can be grown on the semiconductor material 202 and that generates a stress at the interface that is then redistributed in the semiconductor material 202. In one exemplary embodiment, the stress-inducing material is a stress-inducing silicon nitride, although other materials such as silicon germanium and silicon carbide can be used. Methods for depositing tensile stress-inducing materials and compressive stress-inducing materials are well known in the art and need not be described in further detail here. The stress-inducing material 208 then is removed from a first portion 210 of the semiconductor substrate 200 and remains overlying a second portion 212 of the semiconductor substrate 200.

In one exemplary embodiment, after removal of the stress-inducing material 208 from first portion 210, a stress-inducing material 214 is deposited overlying the stress-inducing material 208 and the first portion 210 of the semiconductor substrate 200. In one exemplary embodiment, stress-inducing material 214 exerts a stress opposite to the stress exerted by stress-inducing material 208. Accordingly, if stress-inducing material 208 is a compressive stress-inducing material, stress-inducing material 214 is a tensile stress-inducing material and vice versa. In another embodiment, stress-inducing material 214 exerts the same type of stress as stress-inducing material 208 but the stress is of a different magnitude. Stress-inducing material 214 overlying stress-inducing material 208 then is at least substantially removed and remains overlying first portion 210 of semiconductor substrate 200.

Next, a plurality of sacrificial mandrels 216 are formed overlying stress-inducing material 208 and stress-inducing material 214, as illustrated in FIG. 3. Depending on the materials that form stress-inducing material 208 and stress-inducing material 214, the sacrificial mandrels may comprise a deposited silicon oxide, silicon nitride, silicon oxynitride, polycrystalline silicon, amorphous silicon, or another material suitable for providing mechanical support for sidewall spacers to be formed in a manner described in detail below. In a preferred embodiment of the present invention, stress-inducing materials 208 and 214 both comprise a stress-inducing silicon nitride and sacrificial mandrels 216 comprise polycrystalline silicon. It will be appreciated that all sacrificial mandrels 216 can be formed substantially simultaneously or, alternatively, pluralities of sacrificial mandrels of different composition or dimensions can be formed serially. In one exemplary embodiment, a first plurality 240 of sacrificial mandrels 216 may be formed overlying stress-inducing material 208 and a second plurality 242 of sacrificial mandrels 216, having different dimensions from the first plurality of sacrificial mandrels or spaced a distance different from a distance with which the first plurality are spaced, may be formed overlying stress-inducing material 214. Alternatively, although not illustrated, first plurality 240 and second plurality 242 of sacrificial mandrels may be formed overlying stress-inducing material 208 and sacrificial mandrels with dimensions and/or spacing the same or different from the first plurality 240 and the second plurality 242 may be formed overlying stress-inducing material 214. In this regard, sidewall spacers, discussed below, can be formed with various dimensions and/or can be spaced apart by various distances.

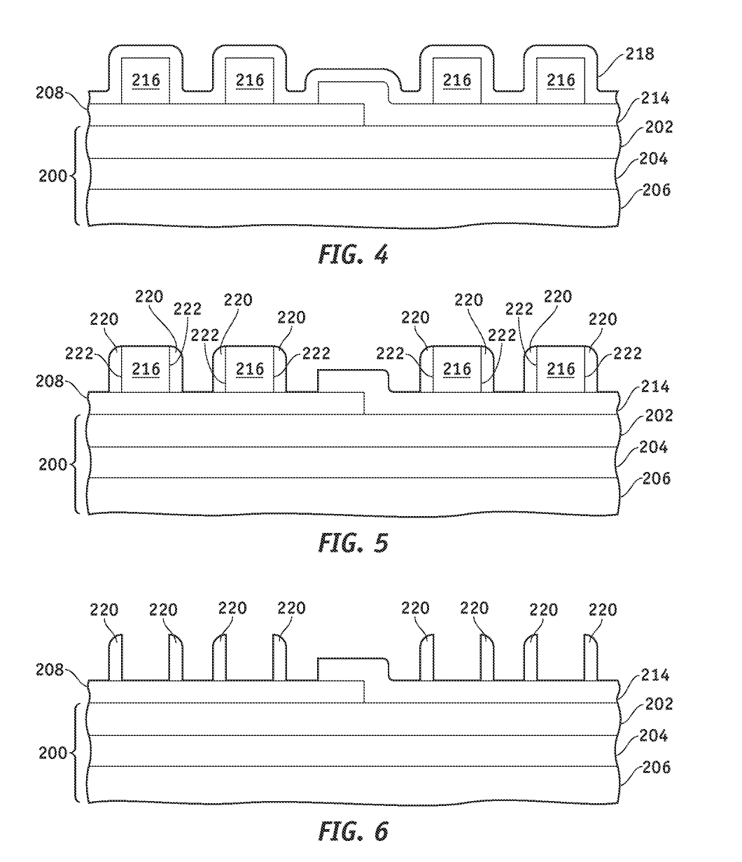

Referring to FIG. 4, a sidewall spacer-forming material 218 is blanket-deposited overlying mandrels 216. The sidewall spacer-forming material 218 comprises a material that has a different etch rate from the material of sacrificial mandrels 216, stress-inducing material 208, and stress-inducing material 214. In this regard, spacers fabricated from sidewall spacer-forming material 218 can be precisely controlled so as to produce spacers of desired dimensions. Materials suitable for sidewall spacer-forming material 218 include, for example, silicon nitride and silicon oxide. In one preferred embodiment, sidewall spacer-forming layer 218 comprises a silicon oxide, stress-inducing materials 208 and 214 both comprise a stress-inducing silicon nitride, and sacrificial mandrels 216 comprise polycrystalline silicon. While FIG. 4 illustrates one sidewall spacer-forming material 218 deposited over sacrificial mandrels 216, it will be appreciated that sidewall spacer-forming material 218 may comprise two, three, or more sub-sidewall spacer-forming materials deposited over each other and/or over various regions of semiconductor substrate 200. In this regard, sidewall spacers of various dimensions can be formed so that fins, described in more detail below, of various dimensions can be formed.

The method continues, as illustrated in FIG. 5, with an anisotropic etch of the sidewall spacer-forming material 218 to form sidewall spacers 220 about sidewalls 222 of sacrificial mandrels 216. In one exemplary embodiment, the sidewall spacers 220 are formed substantially simultaneously by a blanket anisotropic etch. In another exemplary embodiment, rather than being formed substantially simultaneously, the sidewall spacers 220 are formed in groups by separate etch processes. In this regard, sidewall spacers having different dimensions can be formed.

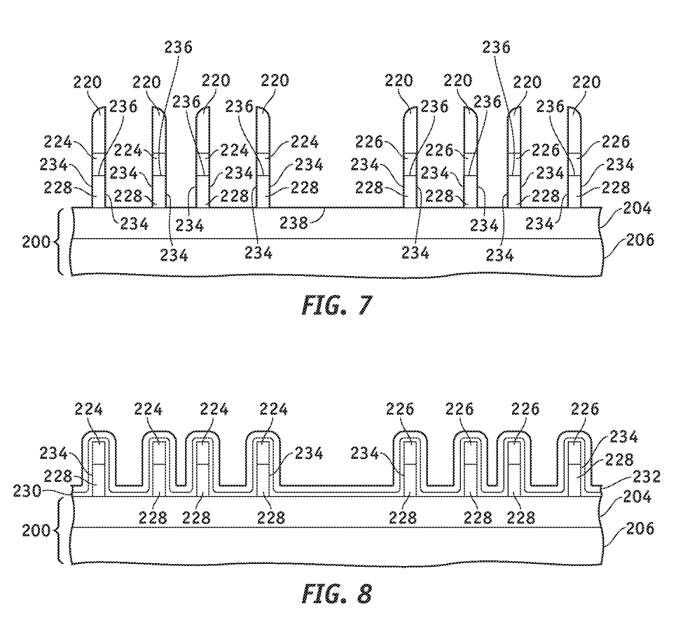

Next, after formation of the sidewall spacers 220, the mandrels are removed using an etch chemistry suitable for etching the mandrels while leaving the sidewall spacers substantially in tact, as illustrated in FIG. 6. Using the sidewall spacers 220 as an etch mask, the stress-inducing materials 208 and 214 are etched, as illustrated in FIG. 7, to form stress-inducing caps 224 and 226, respectively. While stress-inducing material 208 and stress-inducing material 214 are illustrated in FIG. 7 as being etched simultaneously, alternatively, stress-inducing material 208 can be etched before stress-inducing material 214 or stress-inducing material 214 can be etched before stress-inducing material 208. The stress-inducing caps 224 and 226 then are used as etch masks during the etching of the semiconductor material 202 to form fins 228 from semiconductor material 202, leaving the semiconductor substrate 200 now formed of buried oxide layer 204 and support substrate 206. In one exemplary embodiment (not shown), the sidewall spacers 220 then are removed from the etched stress-inducing materials. In an alternative embodiment, the sidewall spacers 220 are removed from the stress-inducing caps 224 and 226 before semiconductor material 202 is etched so that the aspect ratio of the etched stress-inducing materials will be less than the aspect ratio of the sidewall spacers and the etched stress-inducing materials combined. In this regard, maximum control of the subsequent etching of the semiconductor layer 202 can be achieved so as to accurately transfer the width of the stress-inducing caps to the fins. As illustrated in FIG. 7, fins 228 each have sidewalls 234 substantially perpendicular to a surface 238 of semiconductor substrate 200. Fins 228 also have a surface 236 substantially orthogonal to the sidewalls 234 and substantially parallel to but remote from surface 238 of semiconductor substrate 200. The stress-inducing caps 224 and 226 are disposed on surface 236 of fins 228. In this regard, the stress induced in the sidewalls 234 is opposite to that induced on the surface 236. Thus, a compressive stress-inducing cap may be formed overlying n-channel FinFET fins to induce a tensile stress in the sidewalls of the fins and a tensile stress-inducing cap may be formed overlying p-channel FinFET fins to induce a compressive stress in the sidewalls of the fins.

Referring to FIG. 8, after the formation of fins 228, a gate insulator layer 230 is formed about fins 228 such that the gate insulator 230 is proximate the sidewalls 234 of fins 228. The gate insulator layer may be a thermally grown silicon dioxide formed by heating silicon fins 228 in an oxidizing ambient or, as illustrated, may be a deposited insulator such as a silicon oxide, silicon nitride, a high dielectric constant insulator such as HfSiO, or the like. Deposited insulators can be deposited by chemical vapor deposition (CVD), LPCVD, or PECVD. In addition to inducing stress into the sidewalls 234 of the fins, the caps 224 and 226 cause the gate insulator layer 230 to be formed substantially uniformly along the sidewalls, even at the corners of the fin where thinning of the gate insulator layer typically occurs when the gate insulator layer wraps around the corners. In accordance with one embodiment of the invention, a layer of gate electrode-forming material 232 then is formed overlying gate insulator layer 230. The gate electrode-forming material may comprise polycrystalline silicon, at least one metal, a combination of both, or the like.

Accordingly, methods for fabricating semiconductor fins having stress-inducing caps, in accordance with exemplary embodiments of the present invention, have been provided. The stress-inducing caps are formed before the fin structures are formed. In this regard, excess stress-inducing material can be removed easily upon formation of the caps. In addition, the stress-inducing caps are disposed at a top surface of the fins. In the case of FinFET devices, with the channel disposed at the sidewalls of the fins adjacent to a gate structure, a stress-inducing cap disposed on the top surface of the fin perpendicular to the sidewalls induces a discrete stress in the crystal lattice of the fin uniformly to both sidewalls and the stress is induced directly upon the channel of the device.

While at least one exemplary embodiment has been presented in the foregoing detailed description of the invention, it should be appreciated that a vast number of variations exist. It should also be appreciated that the exemplary embodiment or exemplary embodiments are only examples, and are not intended to limit the scope, applicability, or configuration of the invention in any way. Rather, the foregoing detailed description will provide those skilled in the art with a convenient road map for implementing an exemplary embodiment of the invention, it being understood that various changes may be made in the function and arrangement of elements described in an exemplary embodiment without departing from the scope of the invention as set forth in the appended claims and their legal equivalents.

What is claimed is:

1. Method for fabricating stressed structures of a semiconductor device, the method comprising the steps of:
forming a first stress-inducing material overlying a semiconductor material;
forming spacers overlying the first stress-inducing material;
etching the first stress-inducing material using the spacers as an etch mask to form a plurality of first stress-inducing caps; and
etching the semiconductor material using the plurality of first stress-inducing caps as an etch mask.

2. The method of claim 1, wherein the step of forming a first stress-inducing material comprises forming the first stress-inducing material overlying a first portion of the semiconductor material and further comprising the steps of:
forming a second stress-inducing material overlying a second portion of the semiconductor material;
forming spacers overlying the second stress-inducing material;
etching the second stress-inducing material using the spacers as an etch mask to form a plurality of second stress-inducing caps; and
etching the semiconductor material using the plurality of second stress-inducing caps as an etch mask.

3. The method of claim 2, wherein the step of forming the spacers overlying the second stress-inducing material and the step of forming the spacers overlying the first stress-inducing material are performed substantially simultaneously.

4. The method of claim 2, wherein the step of etching the second stress-inducing material and the step of etching the first stress-inducing material are performed substantially simultaneously.

5. The method of claim 2, wherein the step of forming a first stress-inducing material comprises forming one of a tensile stress-inducing material or a compressive stress-inducing material and the step of forming a second stress-inducing material comprises forming the other of the tensile stress-inducing material or the compressive stress-inducing material.

6. The method of claim 1, wherein the step of forming spacers comprises the steps of:
forming sacrificial mandrels overlying the first stress-inducing material;
forming a sidewall spacer-forming material overlying the sacrificial mandrels;
anisotropically etching the sidewall spacer-forming material; and
removing the sacrificial mandrels.

7. The method of claim 6, wherein the step of forming the sacrificial mandrels comprises forming a first plurality of sacrificial mandrels and a second plurality of sacrificial mandrels, the first plurality and the second plurality having different dimensions.

8. The method of claim 6, wherein the step of forming the sacrificial mandrels comprises forming a first plurality of sacrificial mandrels and a second plurality of sacrificial mandrels, and wherein the first plurality of sacrificial mandrels are spaced a first distance from each other and the second plurality of sacrificial mandrels are spaced a second distance from each other, and the first distance and the second distance are different.

9. The method of claim 6, wherein the step of forming a first stress-inducing material comprises forming a first silicon nitride stress-inducing material, wherein the step of forming spacers comprises forming silicon oxide spacers, and wherein the step of forming sacrificial mandrels comprises forming sacrificial polycrystalline mandrels.

10. The method of claim 1, further comprising the step of removing the spacers before the step of etching the semiconductor material.

11. The method of claim 1, wherein the step of etching the semiconductor material further comprises forming fins having sidewalls and further comprising the step of forming a gate insulator layer about the sidewalls of the fins.

12. A method for fabricating stressed fins of a FinFET device, the method comprising the steps of:
depositing a first stress-inducing material overlying a first portion and a second portion of a semiconductor material;
removing the first stress-inducing material from overlying the second portion of the semiconductor material;
depositing a second stress-inducing material overlying the first stress-inducing material and the second portion of the semiconductor material;
at least substantially removing the second stress-inducing material from the first stress-inducing material;
forming sacrificial mandrels overlying the first stress-inducing material and the second stress-inducing material, the sacrificial mandrels having sidewalls;
forming sidewall spacers about the sidewalls of the sacrificial mandrels;
removing the sacrificial mandrels, leaving the sidewall spacers substantially in tact;
etching the first stress-inducing material using the sidewall spacers as an etch mask to form a plurality of first stress-inducing caps;
etching the second stress-inducing material using the sidewall spacers as an etch mask to form a plurality of second stress-inducing caps;
etching the semiconductor material using the plurality of first stress-inducing caps and the plurality of second stress-inducing caps as an etch mask to form fins having sidewalls;
forming a gate insulator layer about the sidewalls of the fins; and
forming a gate electrode-forming material overlying the gate insulator layer.

13. The method of claim 12, wherein the step of etching the first stress-inducing material and the step of etching the second stress-inducing material are performed substantially simultaneously.

14. The method of claim 12, further comprising the step of removing the sidewall spacers before the step of etching the semiconductor material.

15. The method of claim 12, wherein the step of forming the sacrificial mandrels comprises forming a first plurality of sacrificial mandrels and a second plurality of sacrificial mandrels, the first plurality and the second plurality having different dimensions.

16. The method of claim 12, wherein the step of forming the sacrificial mandrels comprises forming a first plurality of sacrificial mandrels and a second plurality of sacrificial mandrels, each sacrificial mandrel of the first plurality being spaced from an adjacent sacrificial mandrel of the first plurality by a first distance and each sacrificial mandrel of the second plurality being spaced from an adjacent sacrificial mandrel of the second plurality by a second distance, the first distance being different from the second distance.

17. The method of claim 12, wherein the step of forming the sidewall spacers comprises forming the sidewall spacers such that the sidewall spacers overlying the first stress-inducing material have dimensions or spacing different from those of the sidewall spacers overlying the second stress-inducing material.

18. The method of claim 12, wherein the step of depositing a first stress-inducing material comprises depositing a first silicon nitride stress-inducing material, wherein the step of depositing a second stress-inducing material comprises depositing a second silicon nitride stress-inducing material, wherein the step of forming sacrificial mandrels comprises forming polycrystalline silicon sacrificial mandrels, and wherein the step of forming sidewall spacers comprises forming silicon oxide sidewall spacers.

19. The method of claim 12, wherein the step of depositing a first stress-inducing material comprises depositing one of a tensile stress-inducing material or a compressive stress-inducing material and the step of depositing a second stress-inducing material comprises depositing the other of the tensile stress-inducing material or the compressive stress-inducing material.

20. A FinFET device comprising:
a plurality of fin structures overlying a semiconductor substrate, each of the plurality of fin structures having sidewalls and a surface orthogonal to the sidewalls and parallel to but remote from a surface of the semiconductor substrate;
a plurality of stress-inducing caps, each of the plurality of stress-inducing caps disposed on the surface of one of the plurality of fin structures; and
a gate insulator layer about the sidewalls of the plurality of fin structures; and
a gate electrode overlying the gate insulator layer.
